(19) United States
(12) Patent Application Publication
(10) Pub. No.: US 2018/0183014 A1
(43) Pub. Date: Jun. 28, 2018

(54) LIGHT EMITTING DEVICE

(71) Applicant: INT TECH CO., LTD., Hsinchu County (TW)

(72) Inventors: PING-I SHIH, HSINCHU COUNTY (TW); YU-HUNG CHEN, TAOYUAN CITY (TW); HSIN-CHE HUANG, TAICHUNG CITY (TW); CHIEN-YU CHEN, TAOYUAN CITY (TW)

(21) Appl. No.: 15/704,607

(22) Filed: Sep. 14, 2017

Related U.S. Application Data
(60) Provisional application No. 62/439,301, filed on Dec. 27, 2016.

(51) Int. Cl. H01L 51/56; H01L 51/00

(52) U.S. Cl. CPC H01L 51/56; H01L 51/0023

(57) ABSTRACT

A mask is designed for patterning organic light emitting material on a surface. The mask includes a substrate having a first surface and a second surface opposite to the first surface. The mask further includes a plurality of holes extended though the substrate with a pitch not greater than 150 um, and each hole having a first exit at the first surface and a second surface at the second surface. At least one of the plurality of holes has a smallest dimension being not greater than about 15 um.

### CROSS-REFERENCE TO RELATED APPLICATIONS

The present application claims priority of U.S. Provisional Patent Application Ser. No. 62/439,301, filed on Dec. 27, 2016, which is incorporated herein by reference in its entirety.

### TECHNICAL FIELD

The present disclosure is related to light emitting device. Especially an organic light emitting device and manufacturing method thereof.

### BACKGROUND

Flat panel display becomes more popular in recent years and is widely adopted from pocket sized electronic devices, such as cell phone, to a wall mount big screen television. Similar to the increasing demanding on the transistor density for IC (Integrated Circuit), the resolution requirement for a display has also been elevated. The resolution of a display highly depends on the density of light emitting units disposed in the display that already shrink the process window for the maker. Moreover, a recent trend to migrate into the flexible display also leads more and more makers selecting the light emitting units from solid state light emitting device to organic type light emitting materials. In view of the above, the display makers are facing more obstacles while trying to catch up the change of the market.

### SUMMARY

A mask is designed for patterning organic light emitting material on a surface. The mask includes a substrate having a first surface and a second surface opposite to the first surface. The mask further includes a plurality of holes extended though the substrate with a pitch not greater than 150 um, and each hole having a first exit at the first surface and a second surface at the second surface. At least one of the plurality of holes has a smallest dimension being not greater than about 15 um.

In some embodiments, the substrate at least includes Ni, or Fe, and in some embodiments the substrate is a stack structure having at least a polymeric layer and a metallic layer disposed thereon.

In some embodiments, the stack structure is a sandwich and the polymeric layer is between the metallic layer and another metallic layer. In some embodiments, first exit has a dimension greater than a dimension of the second exit. In some embodiments, the dimension of the first exit is about 1.5 to 2 times greater than the dimension of the second exit. In some embodiments, a deviation of the pitch within the substrate is not greater than 10%. In some embodiments, the substrate has a Ni concentration between about 5% and about 50%.

A mask for patterning organic light emitting material includes a substrate having an extendable matrix and a stack structure disposed on the extendable matrix. The mask has a plurality of holes extended through the extendable matrix wherein a pitch of a portion of the plurality of holes is not greater than about 150 um.

In some embodiments, the stack structure is arranged in a grid pattern. In some embodiments, the grid pattern has a plurality of grid, and each unit gird surrounds at least two through holes. In some embodiments, the stack structure has a coefficient of thermal expansion (CTE) being not greater than a CTE of the matrix. In some embodiments, the stack structure has a Ni—Fe alloy. In some embodiments, the Ni—Fe alloy has a concentration of Ni being from about 5% to about 50%.

A method of forming a mask includes providing a polymeric substrate and disposing a metallic layer on the polymeric substrate to form a composite structure. The method further includes forming an array of through holes in the composite structure, wherein the array of through holes has a pitch not greater than about 150 um.

In some embodiments, the method includes treating a surface of the polymeric substrate, wherein the surface is configured to receive the metallic layer. In some embodiments, forming an array of through holes in the composite structure is performed by a laser source. In some embodiments, the metallic layer is configured in a grid. In some embodiments, the method includes expanding the polymeric substrate prior to forming the array of through holes. In some embodiments, the method includes forming a photoresist over the polymeric substrate.

### BRIEF DESCRIPTION OF THE DRAWINGS

FIGS. 1A and 1B illustrate an embodiment of a light emitting device.

FIG. 2A to 2C illustrate some embodiments of manufacturing a light emitting device.

FIG. 3A to 31 illustrate a method of manufacturing an apparatus.

FIG. 4 is an SEM picture of a crystalline structure of a metal layer.

FIG. 5A to 5C illustrate some embodiments of an apparatus.

FIG. 6 illustrates a method of manufacturing an apparatus.

FIG. 7A to 7B illustrate some embodiments of an apparatus.

FIG. 8 to FIG. 10 illustrate a method of manufacturing an apparatus.

FIG. 11 illustrates an embodiment of an apparatus.

FIG. 12 to 13 illustrate some embodiments of an apparatus.

FIG. 14 illustrates a though hole in some embodiments of an apparatus.

FIG. 15 illustrates a laser beam source.

FIG. 16 illustrates an embodiment of manufacturing a light emitting device.

### DETAILED DESCRIPTION OF THE DISCLOSURE

The present disclosure is to introduce a method being capable of manufacturing a high density (HD) light emitting display. In the disclosure, the term “high density” is defined as the lighting pixel density is at least equal or greater than 800i. However, the method is also applied for light emitting display with pixel density lower than 800i.

The present disclosure also presents an apparatus that is adopted in manufacturing the high density light emitting display. In some embodiments, the apparatus is mask to be used for a patterning operation. Moreover, the present disclosure also presents a method of manufacturing the apparatus.

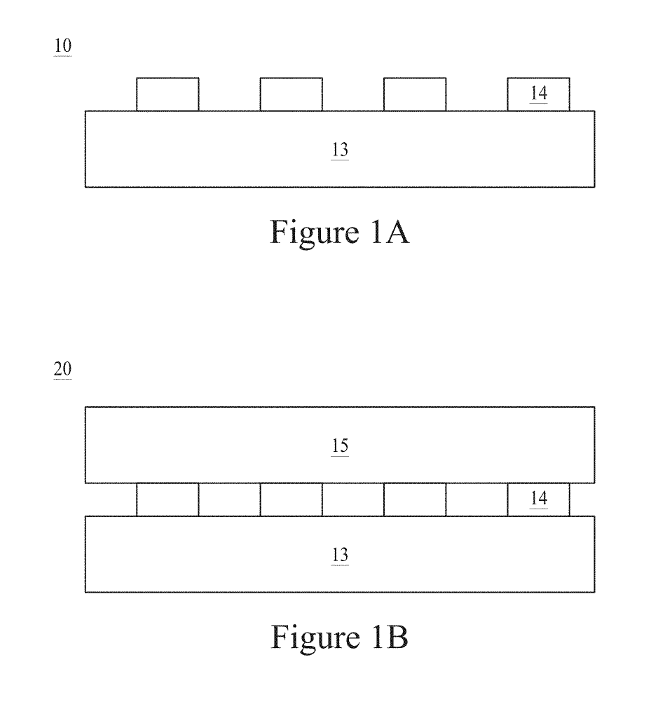

A light emitting display may include at least a light emitting panel, which is sandwiched by an anode and a cathode. In some embodiments, the While forming a light emitting panel, FIGS. 1A and 1B illustrate some exemplary operation steps of manufacturing a light emitting device.

In FIG. 1A, a first substrate 13 is provided and a light emitting layer 14 is disposed on the substrate 13. In some embodiments, the first substrate 13 may be a stack structure and includes several different materials. In some embodiments, the first substrate 13 includes an oxide layer. In some embodiments, the first substrate 13 includes a nitride layer. In some embodiments, the first substrate 13 includes an electrode structure configured to provide electric current to the light emitting layer 14. In some embodiments, the first substrate 13 includes an electron transportation layer (ETL) adjacent to the light emitting layer 14. In some embodiments, the first substrate 13 includes a hole transportation layer (HTL) adjacent to the light emitting layer 14.

The light emitting layer 14 can include organic light emitting material. The light emitting layer 14 can include a plurality of light emitting elements that are mutually separated and disposed on the first substrate 13. In some embodiments, a filling material may be adopted to fill the gap between adjacent light emitting elements.

In FIG. 1B, a second substrate 15 is disposed over the light emitting layer 14 and the substrate 13. In some embodiments, the second substrate 15 may be a stack structure and includes several different materials. In some embodiments, the second substrate 15 includes an oxide layer. In some embodiments, the second substrate 15 includes a nitride layer. In some embodiments, the second substrate 15 includes an electrode structure configured to provide electric current to the light emitting layer 14. In some embodiments, the second substrate 15 includes an electron transportation layer (ETL) adjacent to the light emitting layer 14. In some embodiments, the second substrate 15 includes a hole transportation layer (HTL) adjacent to the light emitting layer 14.

A mask 55 is disposed over the first substrate 13. There may be a gap between a top surface of the first substrate 13 and the mask 55. There are several holes 105 extending through the substrate of mask 55. The substrate of the mask 55 may include several different layers that are laminated through bonding, adhesion, or any suitable process.

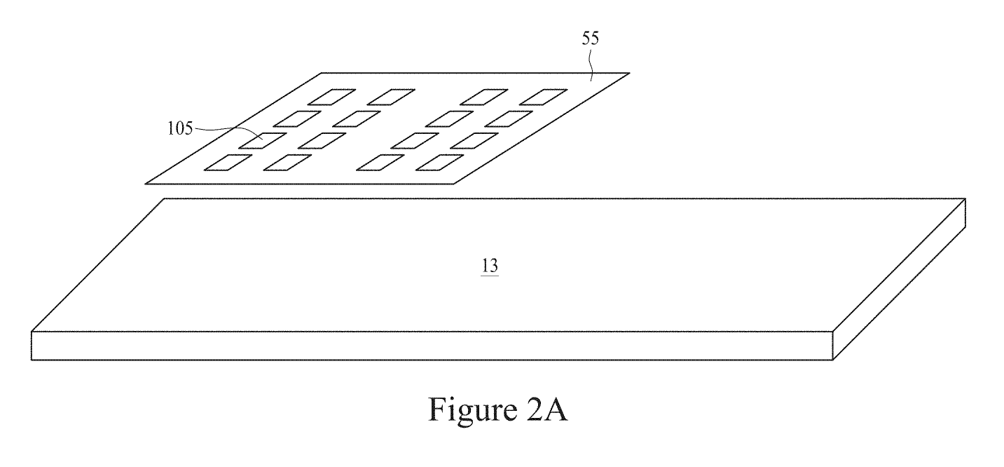

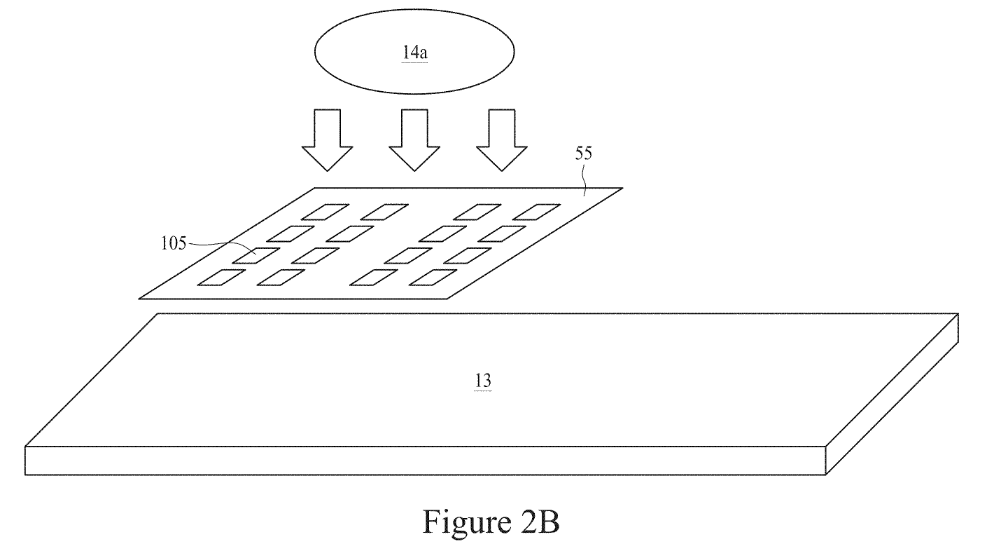

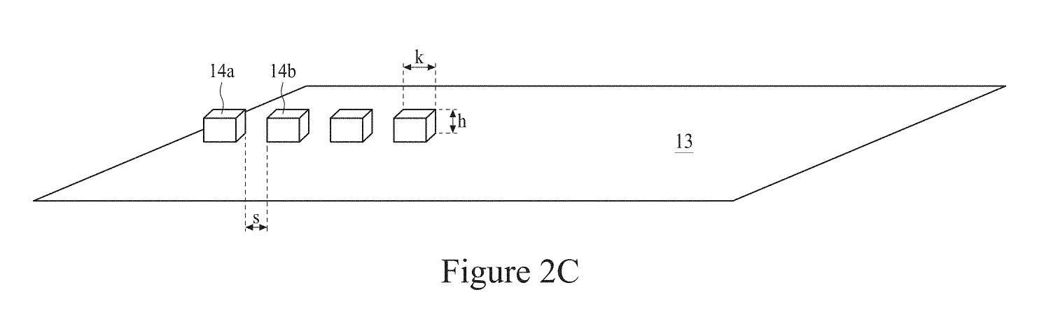

In FIG. 2B, organic light emitting material 14a passes through holes 105 in the mask 55. In some embodiments, there may be more than one type or one color of light emitting material needed for the light emitting device. The sub-step as shown in FIG. 2B may be repeated. Another mask having a pattern different from the mask 55 may be used for a different type of light emitting material.

Patterned organic light emitting layer 14 can be arranged in an array as shown in FIG. 2C, in which several light emitting elements are disposed on the substrate 13. The adjacent light emitting elements, such as 14a and 14b may be configured to emit light with different wavelength. In some embodiments, 14a may be a green light emitting bump and 14b may be a red light emitting element. A spacing, s, of adjacent light emitting elements can be between about 5 um and about 25 um.

A width of a light emitting element, k, can be between about 5 um and about 10 um. A height of a light emitting element, h, can be between about 1 um and about 3 um.

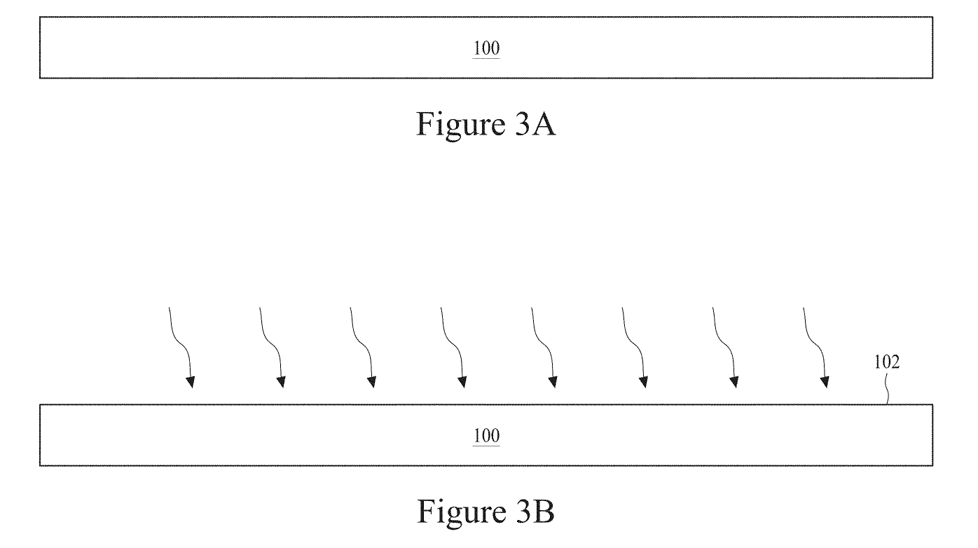

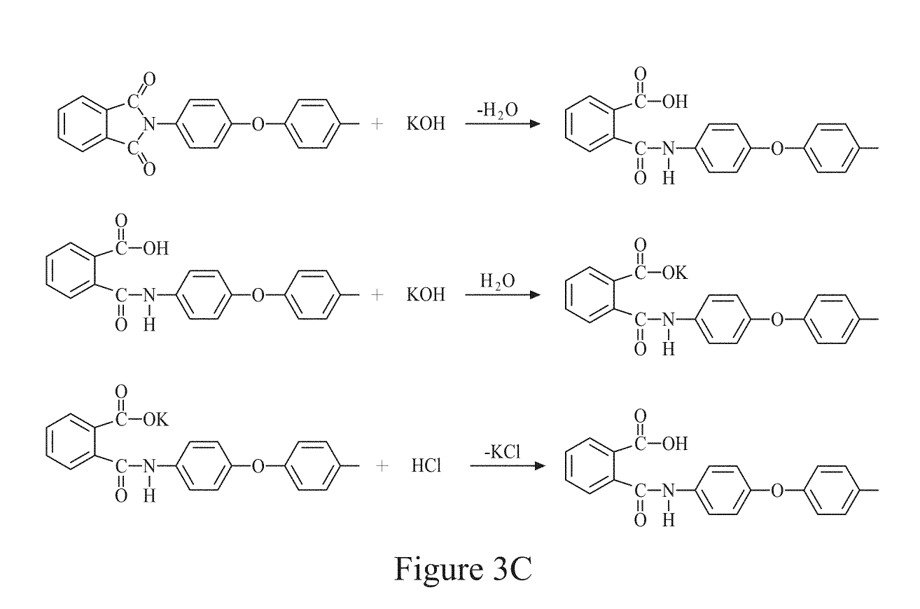

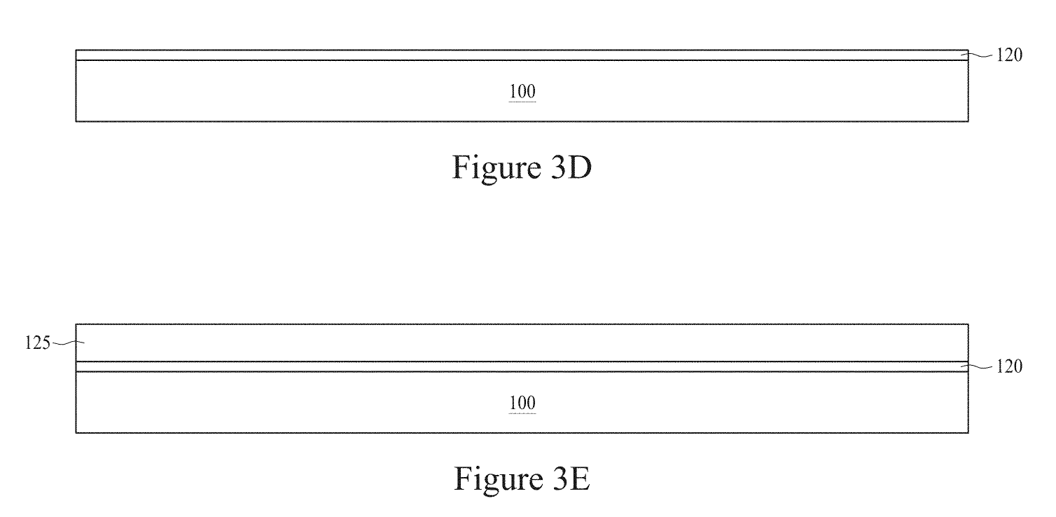

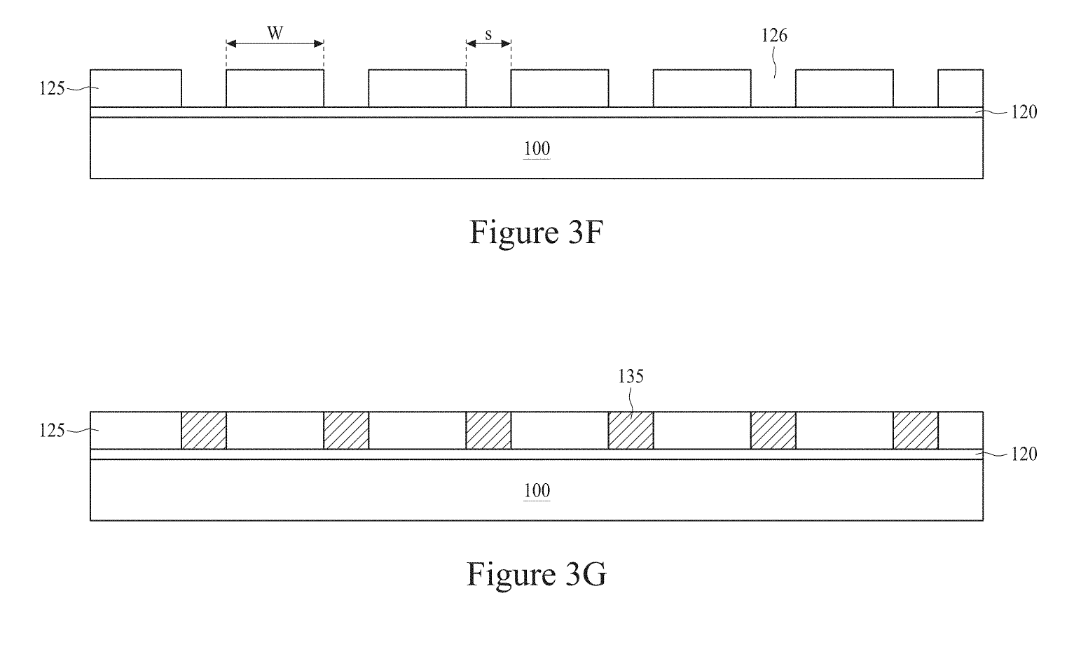

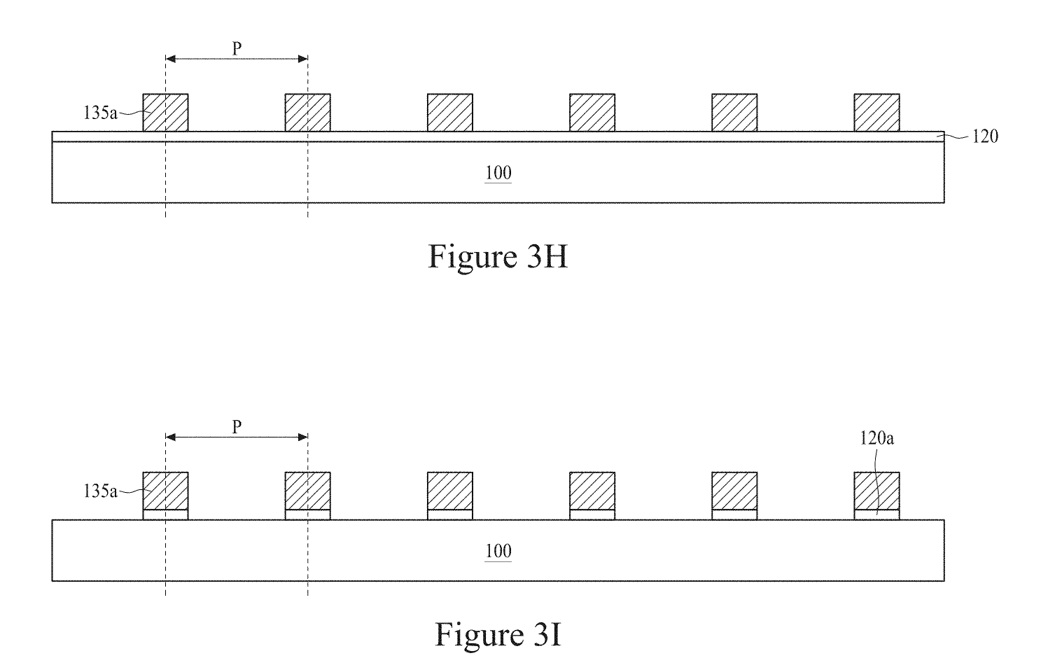

FIG. 3A˜FIG. 3I depict an embodiment including a method of manufacturing a mask as shown in Figure xxx. The mask is used to form a light emitting layer having a high light emitting pixel density. In some embodiments, the mask can form a light emitting panel having density with at least 800 dpi.

A substrate 100 is provided as in FIG. 3A. In some embodiments, the substrate 100 includes an extendable matrix, that is, the substrate 100 can be deformed to a certain degree under an external force. In some embodiments, the matrix of the substrate 100 is substantially formed by polymeric material.

A surface 102 of the substrate 100 is treated as in FIG. 3B. One of the purposes to treat the surface 102 is to activate the surface 102. In some embodiments, the surface 102 is a surface of the substrate 100 designed for heterogeneous bonding.

In some embodiments, the substrate 100 is selected from polyimide. A layer of material including metal or ceramic may be selected to be disposed thereon. In order to improve the adhesion between the surface 102 and the to-be-disposed layer of material, the polyimide surface 102 is treated to enhance the adhesion. The treatment includes utilization of any one of the processes, which includes chemical wet process, photografting, ion beam, plasma and sputtering. The condition such as roughness, density of dangling bond of the surface 102 may be increased after the treatment.

FIG. 3C illustrates some exemplary treatment operations adopting wet process. On the left side is an exemplary formula of the substrate. The surface 102 of the substrate 100 is initially treated with base so as to give the corresponding potassium polyamte. The base used to treat the surface 102 of the substrate 100 may include, but is not limited to, KOH, NaOH, Ba(OH)2, Ca(OH)2, and combinations thereof. In one embodiment, the base is preferably KOH. Excessive base is removed by water rinse. For some cases, the surface 102 of the substrate 100 is further treated with acid. The acid used to treat the surface 102 of the substrate 100 may include, but is not limited to, HCl, HNO3, H2SO4, HClO4, HBr, HI, and combinations thereof. In one embodiment, the acid is HCl. The surface 102 of the substrate 100 can be further dried under vacuum after base or acid treatment. The modified surface 102 of the substrate 100 would be polyamic acids.

After the surface 102 of the substrate 100 is treated, a layer 120 is disposed on the treated surface 102 of the substrate 100 as shown in FIG. 3D. In some embodiments, the layer 120 is a metallic film. In some embodiments, the layer 120 is Pt (platinum). Materials used to create the metallic base layer can include, but are not limited to, palladium, rhodium, platinum, iridium, osmium, gold, nickel, iron, and combinations thereof.

In some embodiments, the layer 120 has a thickness between about 10 nm and about 200 nm. In some embodiments, the layer 120 has a thickness which is about 15% (or less) of a thickness of the substrate 100.

The layer 120 can be disposed on the treated surface 102 through various methods including chemical immersion, E-beam, vapor deposition, atom layer deposition (ALD), etc. One example of forming a platinum metallic base layer 103 is through chemical immersion. The treated surface 102 is bathed in a platinum solution. After formation of a platinum metallic base layer 103 of upon the modified surface 102 of the substrate 100, the substrate 100 is moved from the platinum solution.

FIG. 3D depicts a finished layer 120 on the substrate 100. The layer 120 can act as a seed layer. The layer 120 is then patterned after the formation.

During the patterning operation, a photoresist layer 125 is disposed over layer 120 as in FIG. 3E. Photoresist layer 125 is patterned as in FIG. 3F to form several photoresist (PR) bumps over the layer 120 from a cross sectional perspective. Some of the PR bumps have a width W between about 5 um and 50 um. An opening 126 exists between adjacent PR bumps to partially expose the layer 120 through the opening 126. The opening 126 has a dimension S between about 5 um and 100 um. The dimension S is measured from one sidewall of a PR bump to a facing sidewall of another PR bump adjacent to the PR bump. In some embodiments, the sidewall of PR bump is not a straight vertical surface and may have either a positive or negative slope, and the shortest distance between the sidewall and the facing sidewall. In some embodiments, the dimension S is measured from a top view perspective by a micro scope. And the shortest distance between the adjacent PR bumps still applies to define the dimension S.

In FIG. 3G, the openings 126 in FIG. 3F are filled with material 135. In some embodiments, material 135 is filled in the openings through electroplating (EP). The material 135 has a CTE defined as CTE₁₃₅ in the disclosure.

α is the ratio between substrate's CTE_{substrate} and material 135 CTE₁₃₅.

α=CTE₁₃₅/CTE_{substrate}

In some embodiments, α is between about 0.05 and 1. In some embodiments, a is between about 0.01 and 0.05. In some embodiments, α is between 0.05 and 0.08. In some embodiments, α is between 0.01 and 0.05. In some embodiments, α is between 0.05 and 0.1. In some embodiments, α is between 0.1 and 0.3. In some embodiments, α is between 0.3 and 0.5. In some embodiments, α is between 0.5 and 0.7. In some embodiments, α is between 0.7 and 1.0.

The material 135 has an elastic modulus Y₁₃₅. β is the ratio between the substrate 120 elastic modulus, Y_{sub}, and material 135 elastic modulus, Y₁₃₅.

β=Y₁₃₅/Y_{substrate}

In some embodiments, β is greater than 1. In some embodiments, β is between about 1.05 and about 1.5. In some embodiments, β is between about 1.5 and about 1.75. In some embodiments, β is between about 1.75 and about 2.0. In some embodiments, β is between about 2.0 and about 2.25. In some embodiments, β is between about 2.25 and about 5.0. In some embodiments, β is between about 5.0 and about 10.0. In some embodiments, β is between about 10.0 and about 20.0. In some embodiments, β is between 20.0 and 25.0.

Material 135 may include metallic elements such as Ni, Fe, etc. In some embodiments, the weight percentage of Ni is between about 5% and about 50%. In some embodiments, the weight percentage of Ni is between about 5% and about 10%. In some embodiments, the weight percentage of Ni is between about 10% and about 15%. In some embodiments, the weight percentage of Ni is between about 15% and about 25%. In some embodiments, the weight percentage of Ni is between about 25% and about 35%. In some embodiments, the weight percentage of Ni is between about 35% and about 37%. In some embodiments, the weight percentage of Ni is between about 37% and about 45%. In some embodiments, the weight percentage of Ni is between about 45% and about 50%.

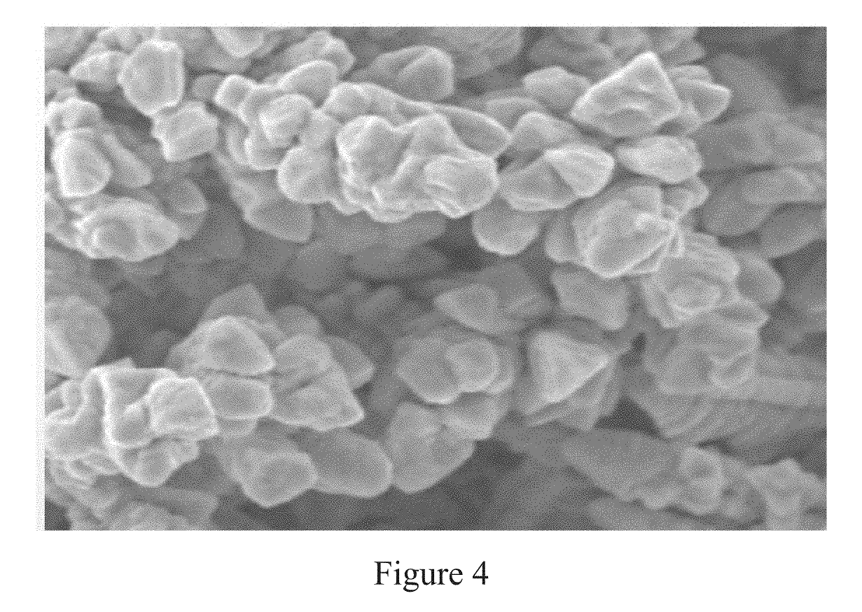

In one embodiment, material 135 may be a Ni—Fe alloy having crystalline structure as shown in FIG. 4. The Ni—Fe alloy is in columnar structure including but no limited to grand shaping with square, circle, star, ellipse and so on. The Ni—Fe alloy has a grain size between about 1 um and 20 um.

After the openings are filled (partially or fully) with material 135, photoresist 125 is removed and leaves several pillars/mesas 135a over layer 120 and substrate 100 as shown in FIG. 3H. The pillars/mesas 135a in FIG. 3H may have a pitch P between about 10 um and about 20 um. In some embodiments, the pitch P is between about 20 um and about 30 um. In some embodiments, the pitch P is between about 30 um and about 40 um. In some embodiments, the pitch P is between about 40 um and about 50 um. In some embodiments, the pitch P is between about 50 um and about 150 um. Pitch P is measured from a central line of a pillar/mesa 135a to a central line of another adjacent pillar/mesa 135a.

In some embodiments, within the substrate 100, the deviation σ of pitch P is not greater than about 5%. In some embodiments, deviation σ of pitch P is not greater than about 3%. In some embodiments, deviation σ of pitch P is not greater than about 2%. In some embodiments, deviation σ of pitch P is not greater than about 1%.

For some other embodiments, layer 120 is also partially removed as in FIG. 3I. A portion of layer 120 (marked as 120a) remain and are disposed under pillars/mesas 135a. In some cases, thickness and profile of portions 120a can be identified by SEM (Secondary Electronic Microscope) and composition of portions 120a can be detected through analysis such as X-ray diffraction. The remained portion 120a may at least include Pt (platinum), Au, Ag, Cu, or other suitable materials.

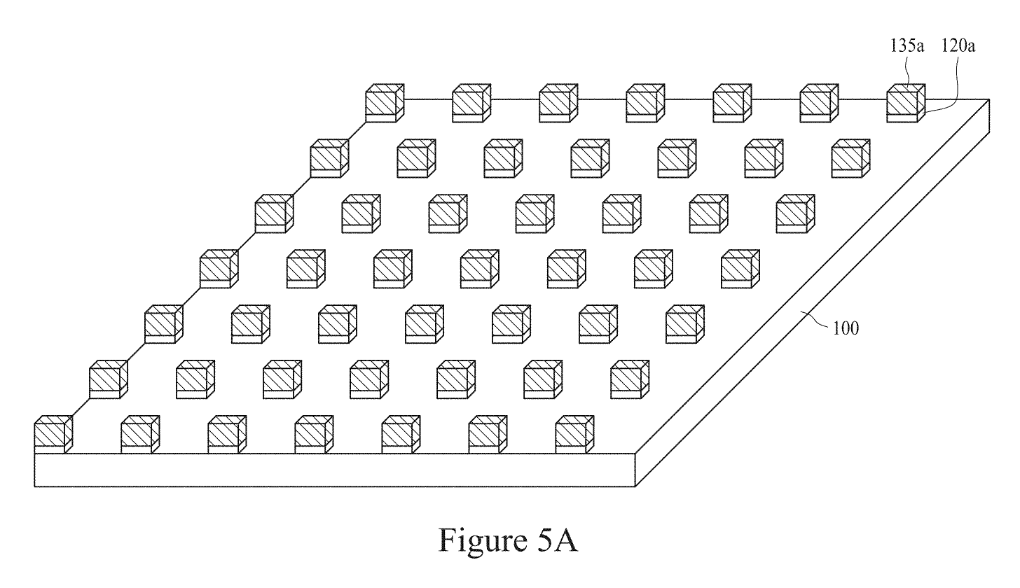

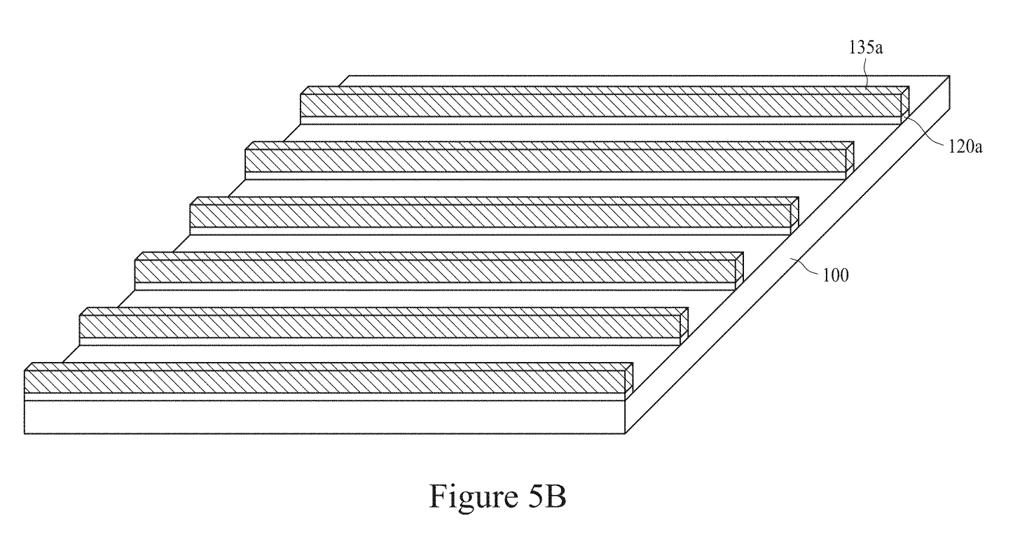

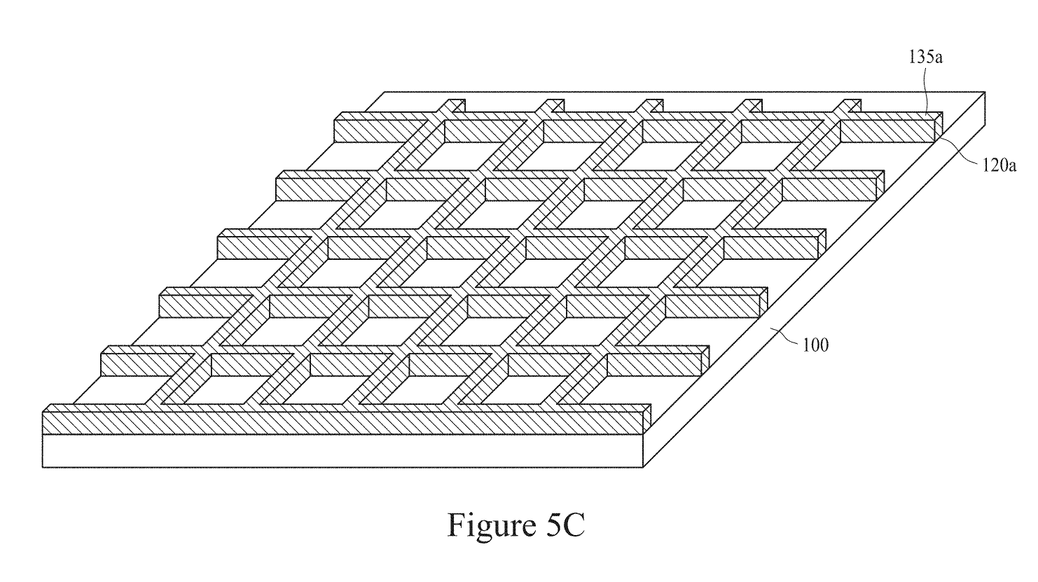

FIG. 5A˜FIG. 5C are perspective views of some embodiments of FIG. 3I. In FIG. 5A, stack 135a/120a are arranged in an array of isolated bumps on the substrate 100. In FIG. 5B, stack 135a/120a are patterned into several separated strips on the substrate 100. In FIG. 5C, stack 135a/120a are patterned as borders of grids on the substrate 100.

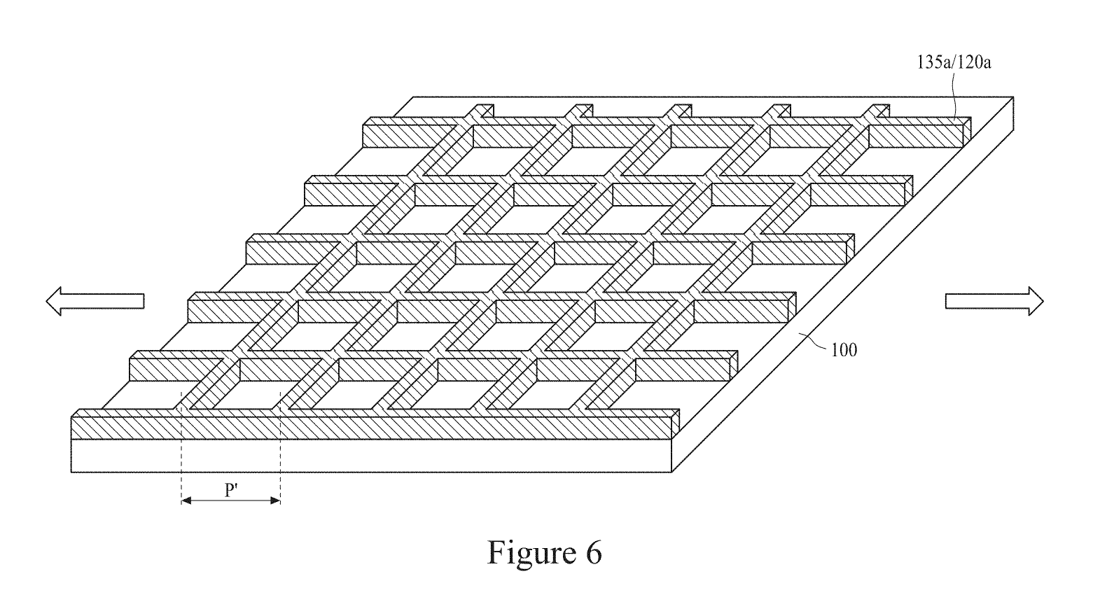

In some embodiments, a force (arrows on both sides) may be applied on the substrate 100 to increase the pitch P. As shown in FIG. 6, the substrate 100 is under tensile stress and expanded. The pitch P′ in FIG. 5A or FIG. 5B may be 10%, or more, greater than the pitch P. In some embodiments, the pitch P′ in FIG. 5A or FIG. 5B may be 15%, or more, greater than the pitch P. In some embodiments, the pitch P′ in FIG. 5A or FIG. 5B may be 20%, or more, greater than the pitch P. In some embodiments, the pitch P′ in FIG. 5A or FIG. 5B may be 25%, or more, greater than the pitch P. When the pitch P′ achieves a predetermined value, a clamp may be disposed on a peripheral the substrate 100 in order to keep the substrate 100 deformed and retain the P′ at the predetermined value.

Since the stack 135a/120 has a higher elastic modulus than that of the substrate 100, the stack 135a/120 prevents the substrate 100 deforming along a direction other than the direction of the applied force as shown in FIG. 6. The stack 135a/120 also helps support the substrate 100 as a frame in order to facilitate proceeding operations.

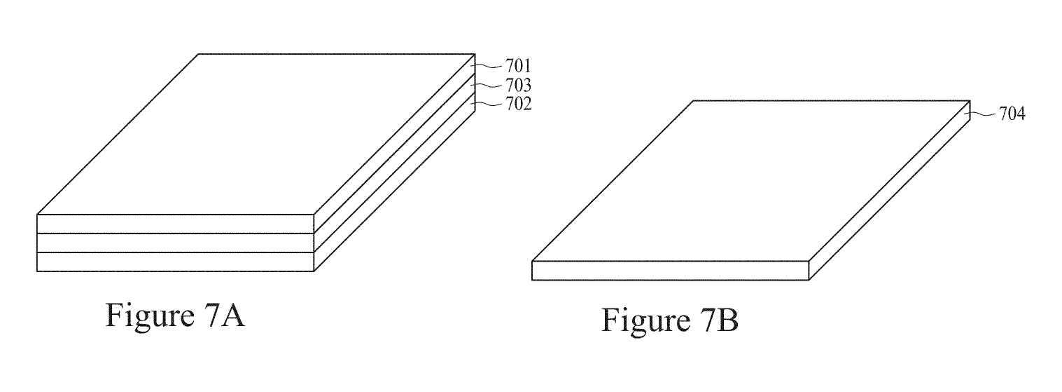

In some embodiments, the mask 55 can be prepared from a substrate as shown in FIG. 7A. In FIG. 7A, the substrate includes at least two different layers (701 or 702, and 703) stacked together. In some embodiments, layer 701 and 702 are both made with metal. In some embodiments, layer 701 and 702 includes nickel, respectively. In some embodiments, layer 703 is a polymeric layer, for example, polyimide. In some embodiments, a CTE of layer 703 is about 1.2 times to about 7 times greater than a CTE of layer 701 or layer 702.

In some embodiments, the mask 55 can be prepared from a substrate as shown in FIG. 7B. In FIG. 7B, the substrate a single layer 704. In some embodiments, layer 704 is made with metal. In some embodiments, layer 704 includes nickel.

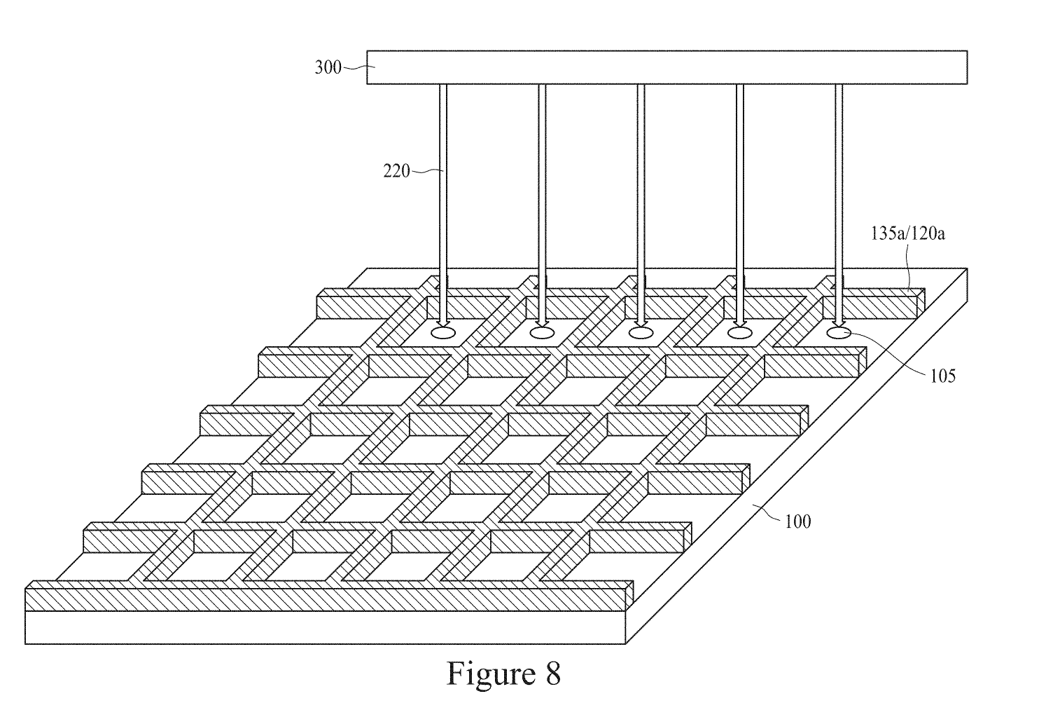

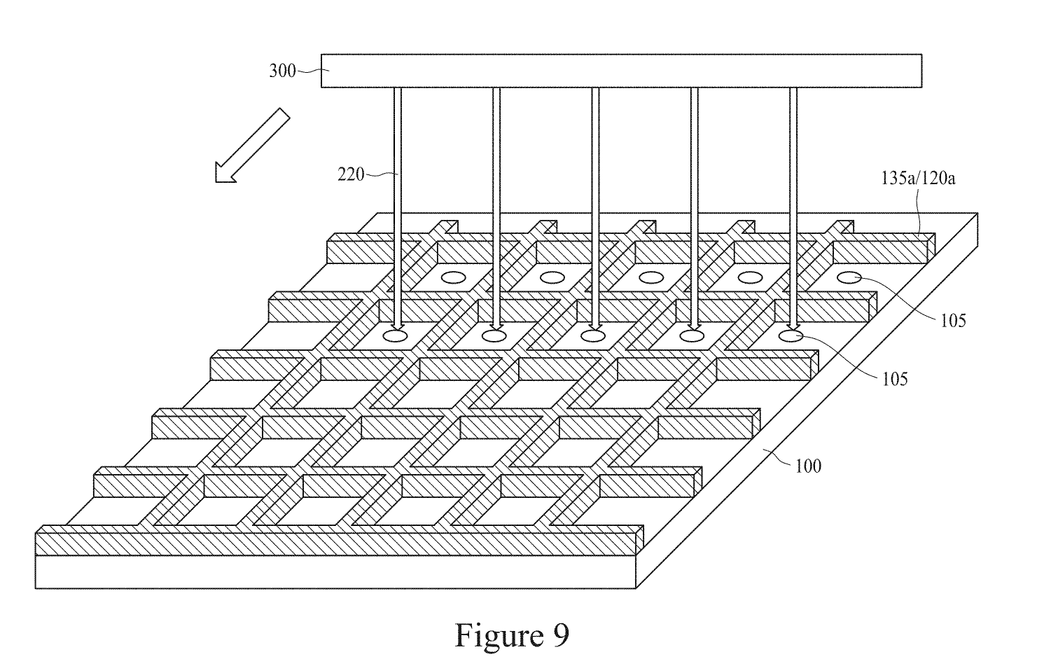

FIG. 8 depicts an operation designed to drill through holes in the substrate 100. In the current embodiment, each unit grid has one through hole 105. A light source 300 is utilized to emit multiple laser beams 220, which may have a wavelength being not greater than 500 nm in order to drill a hole 105. In one embodiment, a KrF laser is used as the beam 220 to from through holes 105. The source 300 may include a single light beam or multiple beams as in FIG. 8. Multiple beam drilling can form a hole per unit grid in several unit grids in one shot as shown in FIG. 8. The light source 300 can also move to a different row or column as shown in FIG. 9. Multiple beam drilling can help improve the throughput.

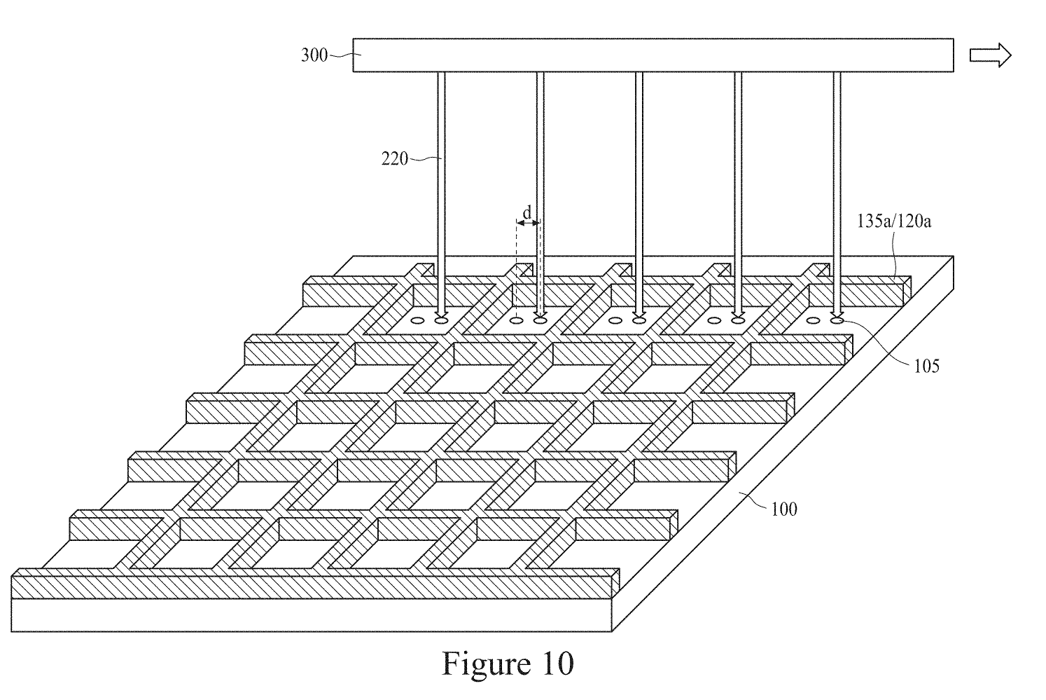

Light source 300 may also shift a certain distance d as in FIG. 10 to drill another hole in a same unit grid during a second shot. In some embodiments, a unit grid may include more than one through hole.

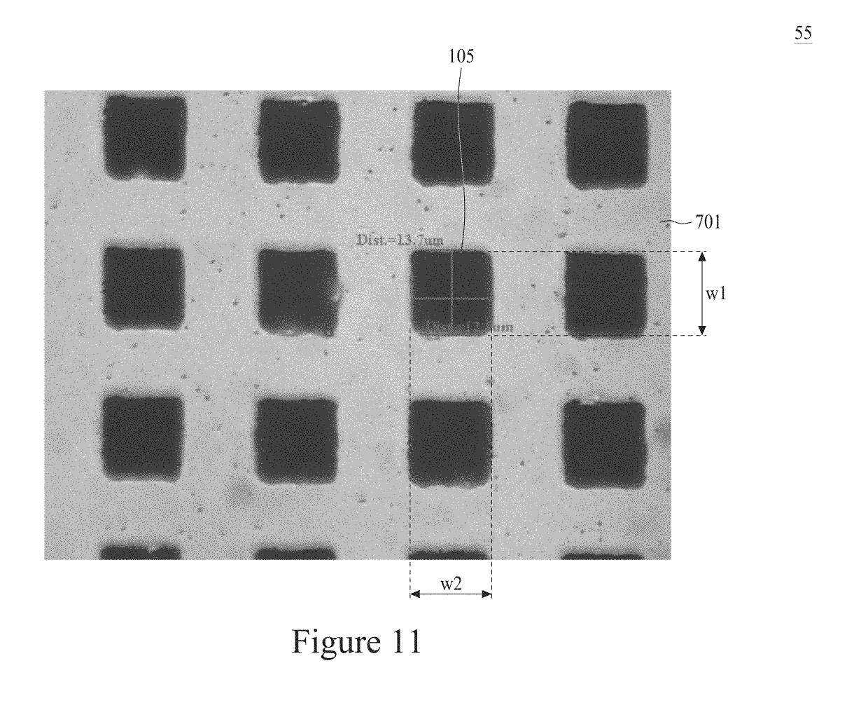

FIG. 11 is a photo showing a portion of a mask 55 viewed from top. There are several holes 105 arranged in an array. Layer 701 is a metallic film and a polymeric layer is there below. A first dimension, w1, is 13.7 um. A second dimension, w2, is 12.1 um. Both dimensions are measured under microscope. In this case, the smallest dimension for the hole 105 is defined as 12.1 um. If the hole 105 is in a circular shape, the smallest dimension is the diameter of the hole measured from top view. For some other shapes, the smallest dimension can be a smallest diagonal measured from top view.

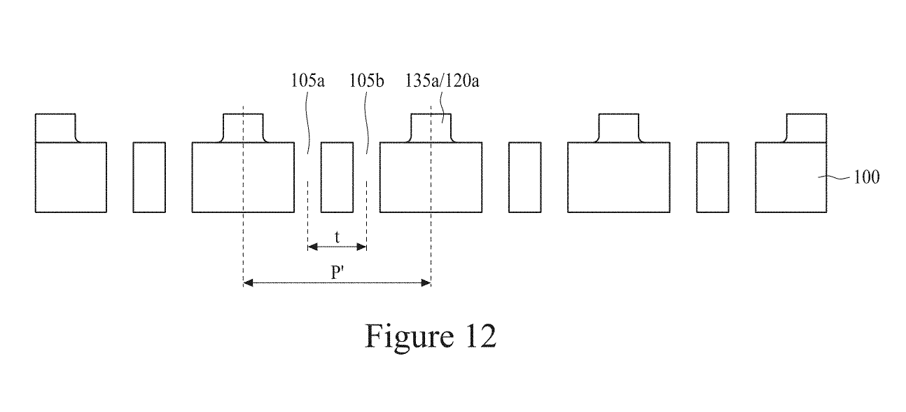

A cross sectional view of a mask formed by drilling a substrate as shown in FIG. 10 is shown in FIG. 12. From cross sectional view perspective, adjacent stacks 135a/120a are separated and have a pitch P′. There are two through holes 105a and 105b located between two stacks 135a/120a, which is also a unit grid. A pitch t, which is smaller than P′, is defined as the distance measured from a central line of hole 105a to a central line of hole 105b. In some embodiments, the pitch t is also substantially equal to the distance d in FIG. 10. In some embodiments, the pitch t is between about 7 um and about 15 um.

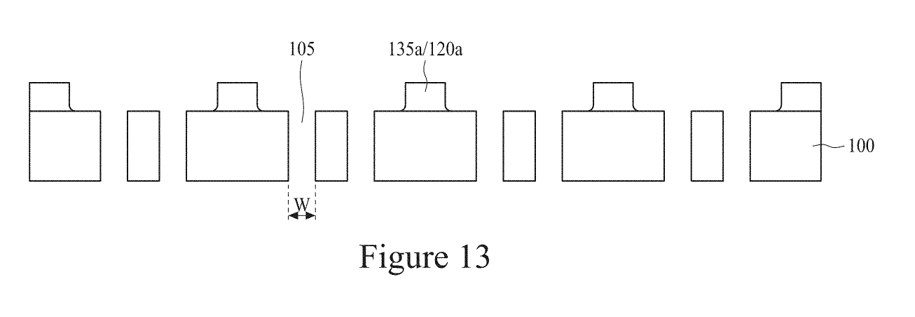

From cross sectional view perspective, the through hole 105 has a smallest dimension w. As shown in FIG. 13, the smallest dimension, w, is measured from one inner sidewall of the hole 105 to an opposing inner sidewall.

In some embodiments, the through hole 105 may have a smallest dimension being not greater than about 20 um. In some embodiments, the smallest dimension of the through hole being not greater than about 15 um.

In addition to the smallest dimension, a largest dimension of the hole can also be controlled. For cases like FIG. 11, w2 is defined as the largest dimension. For circular shape, the diameter is also the largest dimension. In some embodiments, the largest dimension of the hole 105 is not greater than 20 um.

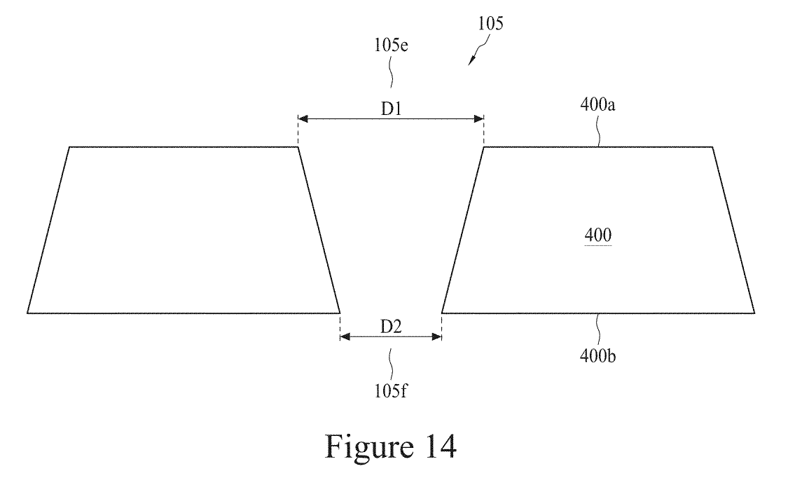

In some embodiments, sizes of two ends of a though hole may differ. As in FIG. 14, the hole 105 is though the substrate 400. Substrate 400 has a first surface 400a and a second surface 400b, which is opposite to the first surface 400a. Hole 105 has two exits 105e and 105f. Exit 105e has a width D1 that is greater than a width D2 of exit 105f. In some embodiments, D1 is about 1.5 to 2 times greater than D2. In some embodiments, exit 105e in configured to be more distal to the substrate 13 in FIG. 2B than exit 105f while disposing organic light emitting material on the substrate 13. In some embodiments, at least one exit of the though hole 105 has a rounding corner. Substrate 400 can have multiple layers as illustrated in previous embodiments.

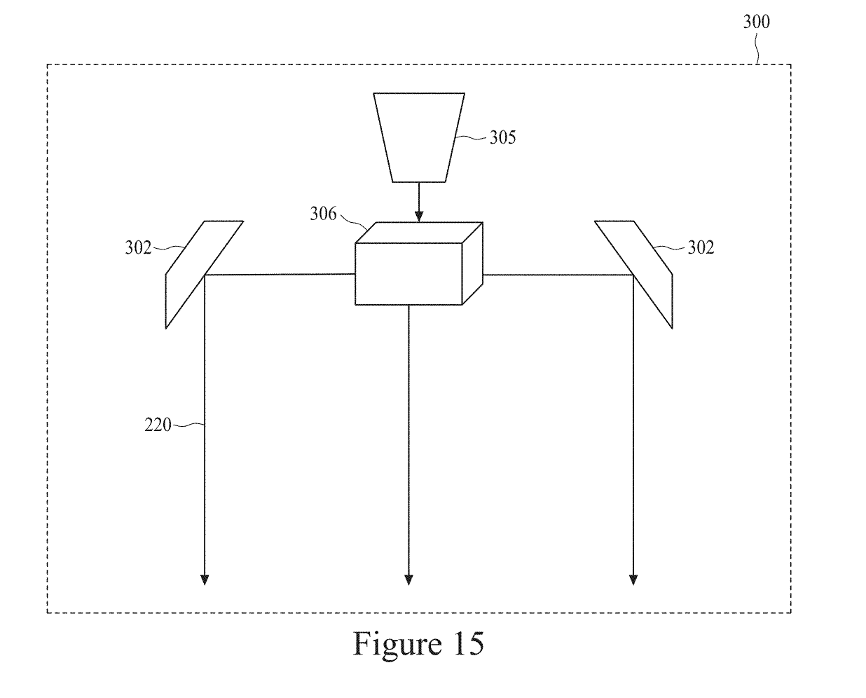

One example of the multi-beam light source 300 is shown in FIG. 15. As in FIG. 15, light source 300 may include a light emitter 305 to emit a single beam. The single beam may have a wavelength less than about 300 nm. In some embodiments, the wavelength is between about 150 nm and about 400 nm.

1 The single beam is diverted into several beams (use three beams as an example) by a splitter 306. The direction of beams emitted from splitter 306 may vary depending on the design of splitter 306. In FIG. 15, beam from light emitter 305 enters into the splitter 306. The splitter 306 generates three different beams including one following the original direction of the entered beam and the other two being perpendicular to the entered beam.

Optical component such as lens 302 is disposed on the travelling path of some beams emitted from the splitter 306 and used to change the direction of beams emitted from the splitter 306. Finally, several parallel light beams 220 can be formed to drill holes on the mask.

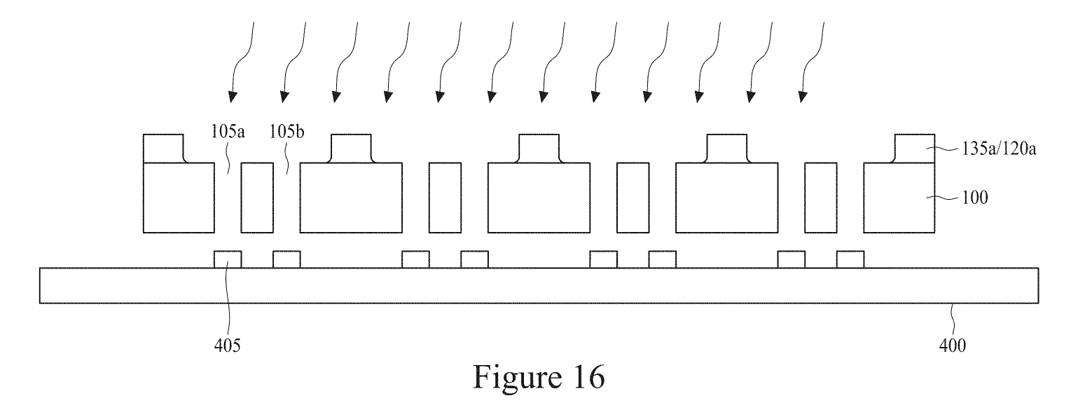

In some embodiments, the mask in FIG. 16 is disposed over a substrate 400. Light emitting material on the other side of the mask may penetrate through the holes 105a and 105b then reach a top surface of the substrate and form a mesa 405. To follow the hole pattern of the mask, several mesas 405 can be formed in an array or other desired pattern.

In some embodiments, mesa 405 is able to emit light. In some embodiments, mesa 405 includes organic light emitting material. In some embodiments, adjacent mesas 405 have a pitch being not greater than about 6 um.

The foregoing outlines features of several embodiments so that persons having ordinary skill in the art may better understand the aspects of the present disclosure. Persons having ordinary skill in the art should appreciate that they may readily use the present disclosure as a basis for designing or modifying other devices or circuits for carrying out the same purposes or achieving the same advantages of the embodiments introduced therein. Persons having ordinary skill in the art should also realize that such equivalent constructions do not depart from the spirit and scope of the present disclosure, and that they may make various changes, substitutions and alternations herein without departing from the spirit and scope of the present disclosure.

1. A mask for patterning organic light emitting material, the mask comprising:
a substrate having a first surface and a second surface opposite to the first surface;
a plurality of holes extended though the substrate with a pitch not greater than 150 um, and each hole having a first exit at the first surface and a second surface at the second surface, wherein at least one of the plurality of holes has a smallest dimension being not greater than about 15 um.

2. The mask in claim 1, wherein the substrate at least includes Ni, or Fe.

3. The mask in claim 1, wherein the substrate is a stack structure having at least a polymeric layer and a metallic layer disposed thereon.

4. The mask in claim 3, wherein the stack structure is a sandwich and the polymeric layer is between the metallic layer and another metallic layer.

5. The mask in claim 1, wherein the first exit has a dimension greater than a dimension of the second exit.

6. The mask in claim 5, wherein the dimension of the first exit is about 1.5 to 2 times greater than the dimension of the second exit.

7. The mask in claim 1, wherein a deviation of the pitch within the substrate is not greater than 10%.

8. The mask in claim 1, wherein the substrate has a Ni concentration between about 5% and about 50%.

9. A mask for patterning organic light emitting material, the mask comprising:
a substrate including an extendable matrix and a stack structure disposed on the extendable matrix;
a plurality of holes extended through the extendable matrix,
wherein a pitch of a portion of the plurality of holes is not greater than about 150 um.

10. The mask in claim 9, wherein the stack structure is arranged in a grid pattern.

11. The mask in claim 10, wherein the grid pattern has a plurality of grid, and each unit gird surrounds at least two through holes.

12. The mask in claim 1, wherein the stack structure has a coefficient of thermal expansion (CTE) being not greater than a CTE of the matrix.

13. The mask in claim 1, wherein the stack structure has a Ni—Fe alloy.

14. The mask in claim 13, wherein the Ni—Fe alloy has a concentration of Ni being from about 5% to about 50%.

15. A method of forming a mask, comprising:
providing a polymeric substrate;
disposing a metallic layer on the polymeric substrate to form a composite structure; and
forming an array of through holes in the composite structure, wherein the array of through holes has a pitch not greater than about 150 um.

16. The method of claim 15, further comprising treating a surface of the polymeric substrate, wherein the surface is configured to receive the metallic layer.

17. The method of claim 15, wherein forming an array of through holes in the composite structure is performed by a laser source.

18. The method of claim 15, wherein the metallic layer is configured in a grid.

19. The method of claim 15, further comprising expanding the polymeric substrate prior to forming the array of through holes.

20. The method of claim 15, further comprising forming a photoresist over the polymeric substrate.
